(19) United States
(12) Patent Application Publication
(10) Pub. No.: US 2007/0158187 A1
(43) Pub. Date: Jul. 12, 2007

(54) Cathode for a vacuum sputtering system

(76) Inventor: Andrew V. Wagner, Pittsburgh, PA (US)

Correspondence Address: Jacques B. Miles;PPG Industries, Inc., One PPG Place, Pittsburgh, PA, 15272, US

(21) Appl. No.: 11/331,288

(22) Filed: Jan. 12, 2006

(51) Int. Cl. C23C 14/00

(52) U.S. Cl. 204/298.02

(57) ABSTRACT

A novel cathode for use in a vacuum sputtering system is disclosed. The cathode includes a cathode core and a first removable portion and a second removable portion on the cathode core.

### FIELD OF THE INVENTION

The present invention relates to a cathode for a vacuum sputtering system, particularly a cathode that includes one or more removable portions which facilitates cathode cleaning.

### BACKGROUND OF THE INVENTION

Materials such as glass and steel are used to make buildings, appliances, cars, etc. Oftentimes, it is necessary to apply a coating(s) over the materials to achieve certain performance properties. Examples of typical coatings include electroconductive coatings, photocatalytic coatings, low emissivity coatings, hydrophilic coatings, hydrophobic coatings, anti-reflective coatings, etc.

The various types of coatings can be applied using conventional application techniques such as CVD, spray pyrolysis, atmospheric plasma deposition and vacuum sputtering deposition which are well known in the art. The use of vacuum sputtering deposition is common across many industries.

In a vacuum sputtering process, a substrate is placed in front of a sputtering target in a vacuum chamber which includes a cathode, a ground shield, etc. The pressure in the chamber is reduced to a high vacuum pressure level then back filled with sputtering gas. A negative voltage is applied to the target to produce a plasma discharge, which is often intensified and confined over the target surface by a magnetic field. The plasma production creates large quantities of positive ions in the sparse gas within the chamber that bombard the target and thereby dislodge atoms or small particles of target material from the surface of the target. Over time, the substrate gets coated with the target material.

A problem with substrates coated by a vacuum sputtering process is they often have spots. The spots typically arise when debris from sources within the coater has gotten on a glass substrate prior to or during coating. When a coating is deposited on the glass, the coating cannot adequately cover the glass because the pieces of debris are typically thousands of times bigger than the coating is thick. Eventually, the debris falls off of the substrate leaving a spot in the coating. In the art, these spots are generally referred to as “pinhole defects”. Pinhole defects are one of the biggest reasons glass coated on vacuum sputtering coating lines has to be discarded.

It has been discovered that most of the debris that causes pinholes comes from debris that builds up on various parts in the vacuum chamber such as the cathode. Debris on a cathode either flakes off during the course of a deposition run or gets knocked loose as a result of a large change in the applied electric field due to arcing (which occurs when insulating material builds up on the target surface).

To remove debris that can potentially cause pinholes, the parts can be polished or sandblasted and ground to roughen the surface of the part. By roughening the surface of a part, debris adheres more strongly to the part and decreases the likelihood the debris will fall off during a coating operation.

In many common deposition sources for vacuum sputtering coating systems, selected parts cannot be conveniently sandblasted. For example, an exterior portion of the cathode core, which is exposed to plasma during a deposition process, cannot be conveniently sandblasted.

The present invention provides a cathode with a cathode core having at least one removable portion. The removable portion can be removed and treated by means of, for example, sandblasting, to get debris off of the surface. The surface can also be roughened so when it is put back in the cathode, the debris adheres more strongly to the surface. Because debris can easily be removed by sandblasting and freshly deposited debris more strongly adheres to the cathode, substrates coated using a vacuum sputtering process that utilizes such a cathode have less pinhole defects.

### SUMMARY OF THE INVENTION

In a non-limiting embodiment, the present invention is a cathode comprising a cathode core and a first removable portion and a second removable portion on the cathode core.

In another non-limiting embodiment, the present invention is a vacuum sputtering system comprising a cathode core; a ground shield around the cathode core; a target; and a first removable portion on the cathode core and a second removable portion on the cathode core.

### DRAWINGS

FIG. 1 shows a schematic cross-sectional view of a vacuum chamber of a magnetron sputtering apparatus that includes a prior art cathode; and

FIG. 2 shows a schematic cross-sectional view of a vacuum chamber of a magnetron sputtering apparatus that includes a cathode according to the present invention.

### DETAILED DESCRIPTION OF THE INVENTION

As used herein, all numbers expressing dimensions, physical characteristics, processing parameters, quantities of ingredients, reaction conditions, and the like, used in the specification and claims are to be understood as being modified in all instances by the term “about”. Accordingly, unless indicated to the contrary, the numerical values set forth in the following specification and claims may vary depending upon the desired properties sought to be obtained by the present invention. At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1.0 to 3.8, 6.6 to 9.7 and 5.5 to 10.

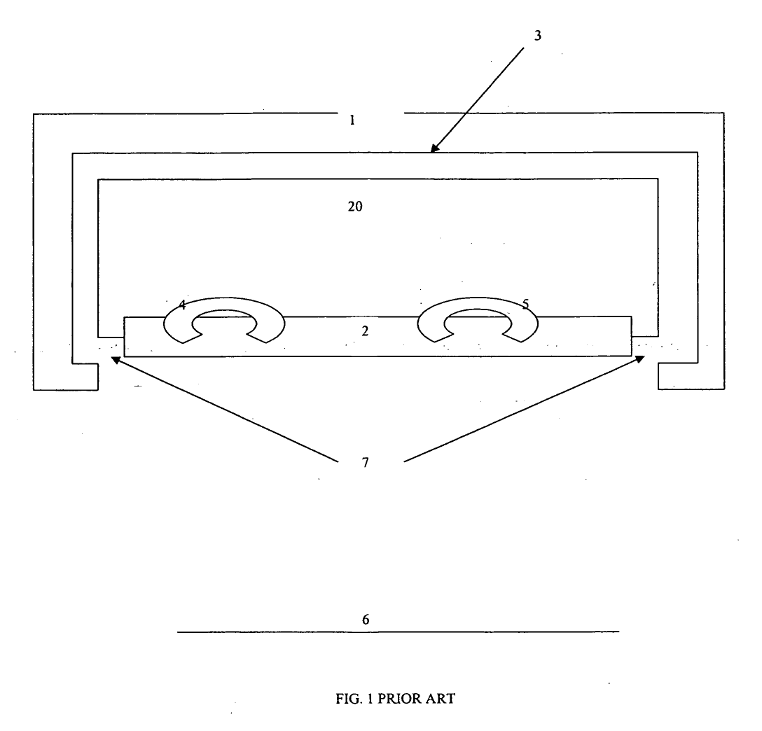

In order to clearly define the present invention, a vacuum chamber of a magnetron sputtering apparatus that includes a prior art cathode of the type which this invention is directed to improving will be described first. As shown in FIG. 1, the vacuum chamber comprises a cathode 3 having a cathode core 20 that has a downwardly facing surface, a ground shield 1 which goes around the cathode 3, a first and second magnet 4 and 5 housed within a cathode core 20, a target 2 positioned along the downward facing surface of the cathode core 20, and a substrate 6 to be coated that faces the target 2.

The core of the cathode 3 includes the first and second magnets 4 and 5 as well as other parts, for example, O-rings, which are not shown. The target 2 is typically a flat slab of material that will be deposited during the sputtering process. All of the parts described above are made of materials and constructed in a manner which is well known in the art.

During a deposition process, an electric field is used to apply negative voltage to the target 2 which produces a plasma discharge. The plasma creates large quantities of positive ions within the vacuum chamber that bombard the target 2 and dislodge atoms of target material from the surface of the target 2 and propel them in the direction of the substrate 6. Over time, the substrate 6 gets coated with the target material.

As can be seen in FIG. 1, there is a gap 7 between the target 2 and the ground shield 1 which is exposed to plasma. Typically, the gap 7 is approximately ¼ inch (0.635 cm) wide. The gap 7 is there because the target 2 and the ground shield 1 need to be at different voltages during a sputtering process. The target 2 is at a voltage between −200 Volts and −1,000 Volts, and the ground shield 1 is at 0 Volts.

During a deposition process, sputtered material can seep into the gap 7 and deposit on the exposed surface of the cathode core 20. Over time, the atoms build up forming debris that falls off and is deposited on the substrate 6 leading to pinhole defects. The exposed surfaces on the cathode 3 are difficult to clean because it is not very accessible. Putting the entire cathode core 20 into a sandblaster is not a suitable option because the cathodes are very heavy (several hundred pounds for an industrial glass coater) and not easy to move. Further, the cathode core 20 could be damaged by the sandblasting process.

Cathodes like the one described above can be purchased from VACT in Fairfield, Calif.

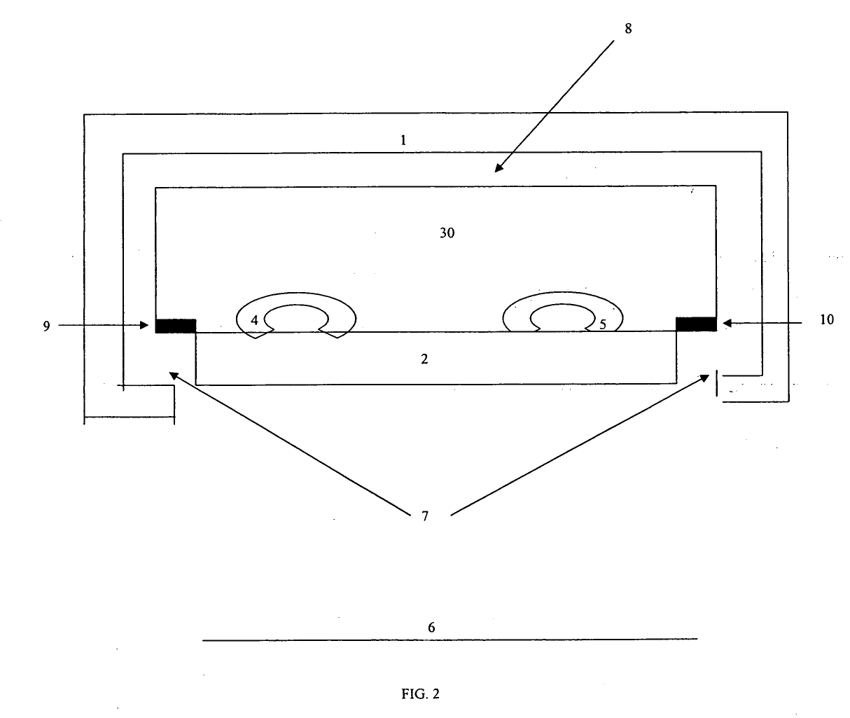

The present invention is a cathode having a cathode core with at least two removable portions that can be used in a typical vacuum chamber. The cathode of the present invention is shown in FIG. 2. All of the parts except the cathode 8 having a cathode core 30 that has a downwardly facing surface in the vacuum chamber are the same in FIG. 1 and FIG. 2. In a non-limiting embodiment, the cathode 8 comprises a non-magnetic metal. For example, the cathode 8 comprises aluminum, copper or stainless steel.

The cathode 8 of the present invention includes removable portions that are the portions of the cathode that are exposed to sputter deposited material, i.e., the portion of the cathode exposed in the gap 7, during a deposition process and thus susceptible to debris buildup. The removable portions can comprise a magnetic material or a non-magnetic material such as aluminum, copper or stainless steel.

In one non-limiting embodiment, the removable portions are portions 9 and 10, which are the portions of the cathode 8 in the vicinity of gap 7. As a result, the removable portions 9 and 10 will at least have the dimensions of the gap 7. For example, the removable portions 9 and 10 can be ¼ inch (0.635 cm) wide and be the length of the cathode. The removable portions 9 and 10 can be secured and unsecured from the cathode 8 in any manner known in the art. For example, the removable portions 9 and 10 can be secured by fasteners, i.e., bolts, slotted receivers or any other manner well known in the art.

The removable portions can be any other portion of the cathode core where debris can build up and periodic cleaning is desired.

The removable portions can be made in any manner known in the art such as by cutting portions out of the conventional cathode shown in FIG. 1.

At an appropriate time, the removable portions 9 and 10 can removed from the cathode 8 and cleaned and/or treated using a process such as sandblasting. The treatment also roughens the surface of the part so that debris will adhere to it better. The described procedure can be repeated as required or used as part of a maintenance program.

As discussed above, the cathode of the present invention can be used in a vacuum sputtering operation as is well known in the art.

By using the cathode of the present invention, companies that have vacuum sputtering operations can realize significant monetary savings. By reducing the amount of substrate, for example, glass, that has to be discarded due to pinhole defects, losses are reduced and significant monetary savings can be realized.

It will be readily appreciated by those skilled in the art that modifications may be made to the invention without departing from the concepts disclosed in the foregoing description. Such modifications are to be considered as included within the scope of the invention. Accordingly, the particular embodiments described in detail herein above are illustrative only and are not limiting as to the scope of the invention, which is to be given the full breadth of the appended claims and any and all equivalents thereof.

We claim:

1. A cathode comprising:
a cathode core; and
a first removable portion and a second removable portion on the cathode core.

2. The cathode according to claim 1, wherein the cathode core comprises a non-magnetic metal.

3. The cathode according to claim 2, wherein the cathode core comprises aluminum, copper or stainless steel.

4. The cathode according to claim 1, wherein the first and second removable portions comprise a non-magnetic metal.

5. The cathode according to claim 4, wherein the first and second removable portions comprise aluminum, copper or stainless steel.

6. The cathode according to claim 1 in a vacuum sputtering system.

7. The cathode according to claim 1, wherein the first and second removable portions are secured to the cathode by fasteners.

8. A vacuum sputtering system comprising:
a cathode core having a downwardly facing surface;
a ground shield having a first edge and a second edge around the cathode core;
a target positioned along the downward facing surface of the cathode core and between the first edge of the ground shield and the second edge of the ground shield, wherein there is a first gap between the target and the first edge of the ground shield and a second gap between the target and the second edge of the ground shield; and
a first removable portion on the cathode core having at least the dimensions of the first gap and a second removable portion on the cathode core having at least the dimensions of the second gap, wherein the first and second removable portions face the target.

9. The cathode according to claim 8, wherein the cathode core comprises a non-magnetic metal.

10. The cathode according to claim 9, wherein the cathode core comprises aluminum, copper or stainless steel.

11. The cathode according to claim 8, wherein the first and second removable portions comprise a non-magnetic metal.

12. The cathode according to claim 11, wherein the first and second removable portions comprise aluminum, copper or stainless steel.
